(19) United States
(12) Patent Application Publication
(10) Pub. No.: US 2007/0177368 A1
(43) Pub. Date: Aug. 2, 2007

(54) Communication product having impact-resistant structure and method for fabricating the same

(75) Inventor: Tse Ming Tsai, Taipei (TW)

Correspondence Address: BACON & THOMAS, PLLC, 625 SLATERS LANE, FOURTH FLOOR, ALEXANDRIA, VA, 22314, US

(73) Assignee: ARIMA COMMUNICATIONS CORPORATION, Taipei County (TW)

(21) Appl. No.: 11/341,449

(22) Filed: Jan. 30, 2006

(51) Int. Cl. H05K 9/00

(52) U.S. Cl. 361/816

(57) ABSTRACT

A communication product includes a circuit board, a shielding frame, a shielding case and an impact-resistant structure. The circuit board has at least an electronic component mounted thereon. The shielding frame is arranged on the circuit board and enclosing the electronic component. The shielding frame has a higher level than the electronic component with respect to the circuit board. The shielding case is secured to the shielding frame and shields the electronic component. The impact-resistant structure includes a first adhesive layer, a second adhesive layer, and a flexible layer sandwiched between the first adhesive layer and the second adhesive layer. The first adhesive layer and the second adhesive layer are attached onto the inner surface of the shielding case and the top surface of the electronic component, respectively.

### FIELD OF THE INVENTION

The present invention relates to a communication product, and more particularly to a communication product having an impact-resistant structure. The present invention also relates to a method for fabricating such as a communication product.

### BACKGROUND OF THE INVENTION

With increasing development of electronic industries, electronic components such as resistors, capacitors, inductors and chips are widely used in communication products, for example mobile phones, personal digital assistants (PDAs). These communication products are operated and controlled by the circuits arranged on the printed circuit board, and driven by some electronic components thereon. Nowadays, since the communication products are developed toward minimization and modulization, many functions are integrated into a single IC module.

For a purpose of simplifying layout of electronic components on the circuit board, reducing noise and allowing for high-density mounting, a surface mount technology (SMT) is widely used to mount the electronic components onto the circuit board.

Generally, the surface mount technology (SMT) comprises the following steps. Firstly, a solder paste is coated onto the contact pads of the circuit board. Then, by using the automatic placement equipment, the surface mount components (or IC modules) are precisely placed on the contact pads. Afterwards, the surface mount components and the circuit board are heated in a reflow furnace to melt the solder paste. The circuit board is then cooled to solidify the solder so as to bond the wire leads of the surface mount components onto the circuit board. Since the wire leads of the surface mount components are thin and crowded, the amount of the solder paste is limited. For further increasing adhesion between the surface mount components and the circuit board, a gluing procedure is necessary to apply glue on the peripheries of the surface mount components. This gluing procedure causes some problems. For example, the gluing procedure is labor-intensive and costly.

Please refer to FIGS. 1(A), 1(B) and 1(C), which schematically illustrate the steps of fabricating a communication product according to the prior art. In FIG. 1(A), the IC modules 11˜15 of the communication product are mounted on a circuit board 1 according to the surface mount technology (SMT), and then the gluing procedure is implemented. For neat drawings, however, only the IC modules 11˜15 are shown in the drawing and the other electronic components are omitted. Examples of the IC modules 11˜15 include but are not limited to a baseband processor IC module, a power amplifier IC module, a transceiver IC module, a power management controller IC module and a memory IC module.

As known, electrostatic discharge (ESD) and electromagnetic interference (EMI) are detrimental to the electronic components on the circuit board 1. For a purpose of minimizing the influence of ESD and EMI, these IC modules should be shielded by electrically conductive material such as metal. As shown in FIG. 1(B), a shielding frame 16 is arranged on the circuit board 1 and encloses these IC modules 11˜15. The shielding frame 16 is made of metal and has a higher level than either of the IC modules 11˜15 with respect to the surface of the circuit board 1. Subsequently, as shown in FIG. 1(C), a metallic shielding case 17 is secured to the shielding frame 16 and thus the IC modules 11˜15 are shielded by the shielding case 17. With such arrangement, the problem of causing electromagnetic interference (EMI) can be effectively solved.

Please refer to FIG. 1(D), which is a cross-sectional view of FIG. 1(C) taken along the line A-A. As shown in FIG. 1(D), there is a height difference between the shielding case 17 and either of the IC modules 11˜15. In other words, the IC module 11˜15 are not in direct contact with the shielding case 17, and the IC modules 11˜15 are secured onto the circuit board 1 by using the solder paste. If the communication product is suffered from a drop or a strong impact, a shear stress may be exerted on the contact portions between the IC module 11˜15 and the circuit board 1. Due to this shear stress, the solder paste on the contact portions is readily fractured. Under this circumstance, the wire leads of the IC module 11˜15 may no longer be electrically connected with the circuit board 1 or even detached from the circuit board 1. Accordingly, the overall communication product may have a breakdown.

Furthermore, for a purpose of inspecting an IC module, the glue on the periphery of the IC module should be removed before the IC module is detached from the circuit board. Likewise, after the IC module is inspected or replaced with a new one, the surface mount technology (SMT) and the gluing procedure as described above should be implemented. Therefore, the disadvantages of using the gluing procedure occur again.

In views of the above-described disadvantages resulted from the conventional method, the applicant keeps on carving unflaggingly to develop a communication product having an impact-resistant structure according to the present invention through wholehearted experience and research.

### SUMMARY OF THE INVENTION

An object of the present invention is to provide a communication product having an impact-resistant structure for avoiding detachment of the electronic components or breakdown of the communication product when the communication product is suffered from a drop or a strong impact.

Another object of the present invention is to provide a communication product having an impact-resistant structure so as to reduce the time and cost of fabricating or inspecting the IC modules thereof.

In accordance with an aspect of the present invention, there is provided a communication product having an impact-resistant structure. The communication product comprises a circuit board, a shielding frame, a shielding case and an impact-resistant structure. The circuit board has at least an electronic component mounted thereon. The shielding frame is arranged on the circuit board and enclosing the electronic component, wherein the shielding frame has a higher level than the electronic component with respect to the circuit board. The shielding case is secured to the shielding frame and shields the electronic component. The impact-resistant structure comprises a first adhesive layer, a second adhesive layer, and a flexible layer sandwiched between the first adhesive layer and the second adhesive layer. The first adhesive layer and the second adhesive layer are attached onto the inner surface of the shielding case and the top surface of the electronic component, respectively.

In an embodiment, the electronic component is an IC module, for example a baseband processor IC module, a power amplifier IC module, a transceiver IC module, a power management controller IC module or a memory IC module.

Preferably, the shielding frame and the shielding case are made of metal.

Preferably, the flexible layer is made of elastomeric material, for example foam or rubber.

In an embodiment, the electronic component is mounted on the circuit board via a surface mount technology.

Preferably, the communication product is a mobile phone or a personal digital assistant.

In accordance with an aspect of the present invention, there is provided a process of fabricating a communication product. Firstly, an electronic component is mounted on a circuit board. Then, a shielding frame is attached on the circuit board and enclosing the electronic component, wherein the shielding frame has a higher level than the electronic component with respect to the circuit board. An impact-resistant structure including a first adhesive layer, a second adhesive layer, and a flexible layer sandwiched between the first adhesive layer and the second adhesive layer is provided. Then, the first adhesive layer of the impact-resistant structure is attached onto the inner surface of a shielding case. Afterwards, the shielding case is secured onto the shielding frame and shields the electronic component such that the second adhesive layer of the impact-resistant structure is attached onto the top surface of the electronic component.

The above contents of the present invention will become more readily apparent to those ordinarily skilled in the art after reviewing the following detailed description and accompanying drawings, in which:

### BRIEF DESCRIPTION OF THE DRAWINGS

FIGS. 1(A), 1(B) and 1(C) are schematic views illustrating the steps of fabricating a communication product according to the prior art;

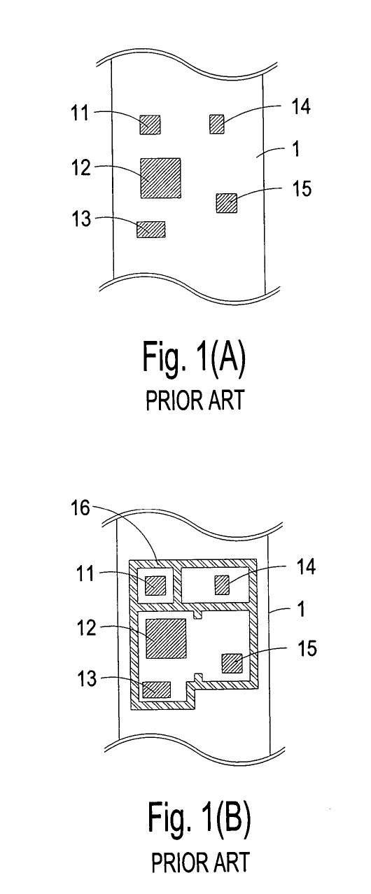

FIG. 1(D) is a cross-sectional view of FIG. 1(C) taken along the line A-A;

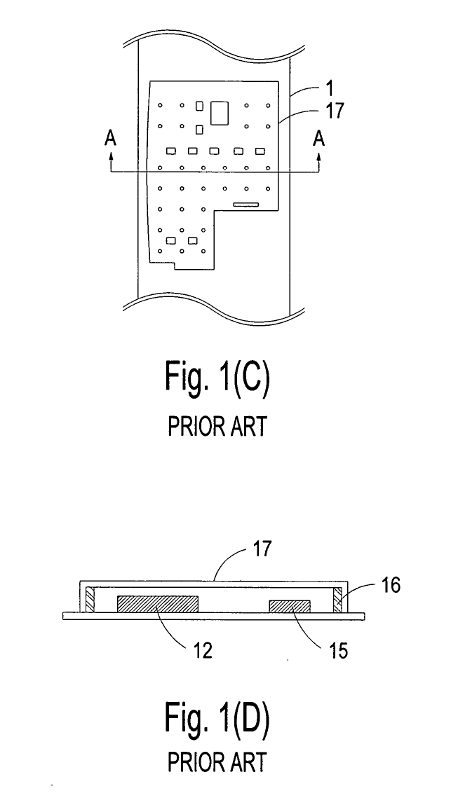

FIGS. 2(A), 2(B) and 2(C) are schematic views illustrating the steps of fabricating a communication product having an impact-resistant structure according to a preferred embodiment of the present invention; and

FIG. 3 is an impact-resistant structure according to a preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

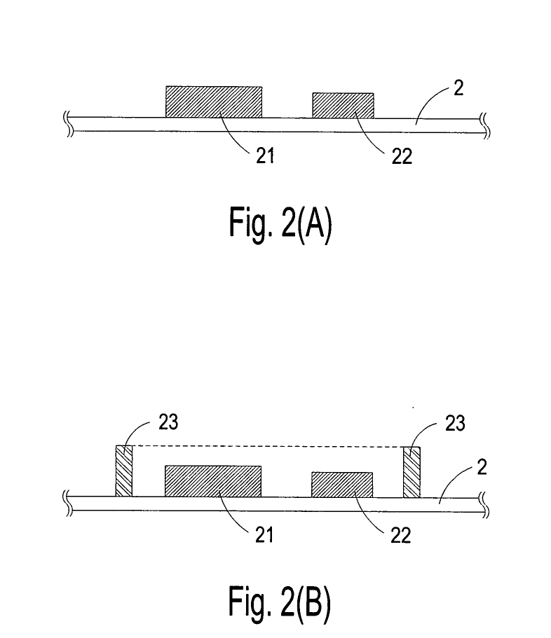

Please refer to FIGS. 2(A), 2(B) and 2(C), which schematically illustrate the steps of fabricating a communication product according to a preferred embodiment of the present invention. In FIG. 2(A), the IC modules of the communication product are mounted on a circuit board 2 according to the surface mount technology (SMT). The operation principle of the surface mount technology (SMT) is well known in the art, and is not to be redundantly described herein. For neat drawings, however, only the IC modules 21 and 22 are shown in the drawing. In the present invention, an exemplary communication product is a mobile phone, a personal digital assistants (PDAs), etc. Examples of the IC modules 21 and 22 include but are not limited to any two of a baseband processor IC module, a power amplifier IC module, a transceiver IC module, a power management controller IC module and a memory IC module.

Subsequently, as shown in FIG. 2(B), a shielding frame 23 is arranged on the circuit board 2 and encloses these IC modules 21 and 22. The shielding frame 23 is made of metal and has a higher level than either of the IC modules 21 and 22 with respect to the surface of the circuit board 2.

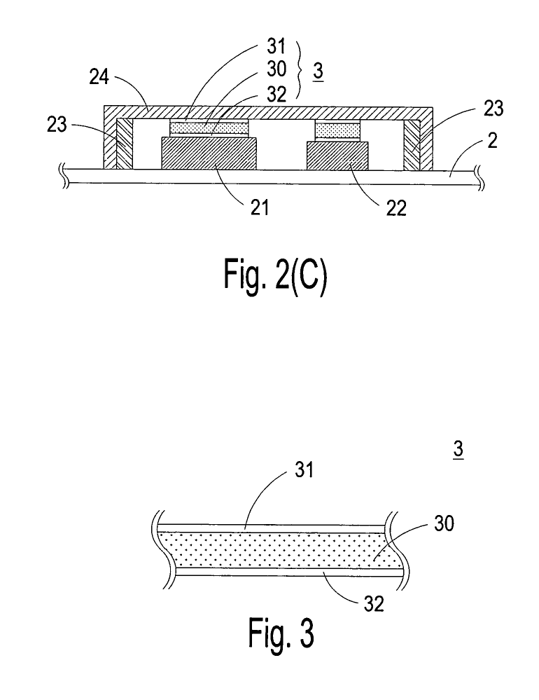

Afterwards, as shown in FIG. 2(C), a metallic shielding case 24 is secured to the shielding frame 23 and thus the IC modules 21 and 22 are shielded by the shielding case 24. With such arrangement, the problem of causing electromagnetic interference (EMI) can be effectively solved. Furthermore, an impact-resistant structure 3 is arranged between the IC module and the shielding case 24. Please also refer to FIG. 3. The impact-resistant structure 3 comprises a first adhesive layer 31, a second adhesive layer 32, and a flexible layer 30 sandwiched between the first adhesive layer 31 and the second adhesive layer 32. The flexible layer 30 is made of elastomeric material such as foam or rubber. The first adhesive layer 31 and the second adhesive layer 32 are attached onto the inner surface of the shielding case 24 and the top surfaces of the IC modules 21 and 22, respectively. Since the IC modules 21 and 22 are in contact with the impact-resistant structure 3 and supported by the shielding case 24, the vibration amplitude of the circuit board 2 is minimized. In addition, if the communication product is suffered from a drop or a strong impact, the flexible layer 30 of the impact-resistant structure 3 may facilitate reducing the shear stress applied on the contact portions between the IC module and the circuit board. Accordingly, the problems associated with detachment of the electronic components or breakdown of the communication product are overcome.

In some embodiments, in the step as shown in FIG. 2(C), the first adhesive layer 31 of the impact-resistant structure 3 has been previously attached onto the inner surface of the shielding case 24 and corresponding to the locations of the IC modules 21 and 22. Later, during the process of securing the shielding case 24 to the shielding frame 23, the second adhesive layer 32 of the impact-resistant structure 3 is simultaneously attached on the top surfaces of the IC modules 21 and 22.

From the above description, the impact-resistant structure of the present invention is capable of avoiding detachment of the electronic components or breakdown of the communication product when the communication product is suffered from a drop or a strong impact. Advantageously, the impact-resistant structure used in the communication product is simple and cost-effective. As previously described, the gluing procedure conventionally used to fabricate the communication product is labor-intensive and costly. According to the present invention, due to the excellent impact resistance provided by the impact-resistant structure, the gluing procedure may be exempted. That is, after the shielding case is opened, the IC module can be directly detached for inspection without removing the glue. After the IC module is inspected or replaced with a new one, the surface mount technology (SMT) is implemented, but the gluing procedure may be omitted.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A communication product having an impact-resistant structure, comprising:
a circuit board having at least an electronic component mounted thereon;
a shielding frame arranged on said circuit board and enclosing said electronic component, wherein said shielding frame has a higher level than said electronic component with respect to said circuit board;
a shielding case secured to said shielding frame and shielding said electronic component; and
an impact-resistant structure comprising a first adhesive layer, a second adhesive layer, and a flexible layer sandwiched between said first adhesive layer and said second adhesive layer, wherein said first adhesive layer and said second adhesive layer are attached onto the inner surface of said shielding case and the top surface of said electronic component, respectively.

2. The communication product according to claim 1 wherein said electronic component is an IC module.

3. The communication product according to claim 2 wherein said IC module is selected from a group consisting of a baseband processor IC module, a power amplifier IC module, a transceiver IC module, a power management controller IC module and a memory IC module.

4. The communication product according to claim 1 wherein said shielding frame is made of metal.

5. The communication product according to claim 1 wherein said shielding case is made of metal.

6. The communication product according to claim 1 wherein said flexible layer is made of elastomeric material.

7. The communication product according to claim 6 wherein said elastomeric material is foam or rubber.

8. The communication product according to claim 1 wherein said electronic component is mounted on said circuit board via a surface mount technology.

9. The communication product according to claim 1 being a mobile phone.

10. The communication product according to claim 1 being a personal digital assistant.

11. A process of fabricating a communication product, comprising steps of:
mounting at least an electronic component on a circuit board;
attaching a shielding frame on said circuit board to enclose said electronic component, wherein said shielding frame has a higher level than said electronic component with respect to said circuit board;
providing an impact-resistant structure comprising a first adhesive layer, a second adhesive layer, and a flexible layer sandwiched between said first adhesive layer and said second adhesive layer;
attaching said first adhesive layer of said impact-resistant structure onto the inner surface of a shielding case; and
allowing said shielding case to be secured onto said shielding frame and shield said electronic component such that said second adhesive layer of said impact-resistant structure is attached onto the top surface of said electronic component.

12. The process according to claim 11 wherein said electronic component is an IC module.

13. The process according to claim 12 wherein said IC module is selected from a group consisting of a baseband processor IC module, a power amplifier IC module, a transceiver IC module, a power management controller IC module and a memory IC module.

14. The process according to claim 11 wherein said shielding frame is made of metal.

15. The process according to claim 11 wherein said shielding case is made of metal.

16. The process according to claim 11 wherein said flexible layer is made of elastomeric material.

17. The process according to claim 16 wherein said elastomeric material is foam or rubber.

18. The process according to claim 11 wherein said electronic component is mounted on said circuit board via a surface mount technology.

19. The process according to claim 11 wherein said communication product is a mobile phone.

20. The process according to claim 11 wherein said communication product is a personal digital assistant.
